(19) United States
(12) Patent Application Publication
(10) Pub. No.: US 2025/0318111 A1
(43) Pub. Date: Oct. 9, 2025

(54) SEMICONDUCTOR DEVICE AND MANUFACTURING METHOD THEREOF

(71) Applicant: NANYA TECHNOLOGY CORPORATION, New Taipei city (TW)

(72) Inventors: Ming-Yang HSIEH, New Taipei City (TW); Ying-Cheng CHUANG, New Taipei City (TW)

(21) Appl. No.: 18/625,431

(22) Filed: Apr. 3, 2024

(51) Int. Cl. H10B 12/00; H01L 21/027

(52) U.S. Cl. CPC H10B 12/50; H01L 21/0276; H10B 12/488

(57) ABSTRACT

A semiconductor device is provided. The semiconductor device includes a substrate, a word line structure, a first gate structure, and a second gate structure. The substrate has an active region and a peripheral region surrounding the active region. The word line structure is disposed in the active region of the substrate. The first gate structure is disposed in the peripheral region of the substrate, wherein a bottom surface of the first gate structure is curved toward the substrate, and the bottom surface of the first gate structure is below a top surface of the substrate. The second gate structure is disposed in the peripheral region of the substrate and the second gate structure located between the word line structure and the first gate structure, wherein a bottom surface of the second gate structure is coplanar with the top surface of the substrate.

### BACKGROUND

### Field of Invention

The present invention relates to a semiconductor device and manufacturing method thereof.

### Description of Related Art

In recent decades, demand to storage capability has increased as electronic products continue to improve. In order to increase storage capability of a memory device (e.g., a DRAM device), more memory cells are integrated in the memory device. As the integration level increases, the semiconductor device becomes smaller. However, small device may induce leakage issue.

Accordingly, the present disclosure provides a semiconductor device and manufacturing method thereof, wherein the semiconductor device in the peripheral region include a curved bottom surface, respectively.

### SUMMARY

In accordance with an aspect of the present disclosure, a semiconductor device is provided. The semiconductor device includes a substrate, a word line structure, a first gate structure, and a second gate structure. The substrate has an active region and a peripheral region surrounding the active region. The word line structure is disposed in the active region of the substrate. The first gate structure is disposed in the peripheral region of the substrate, wherein a bottom surface of the first gate structure is curved toward the substrate, and the bottom surface of the first gate structure is below a top surface of the substrate. The second gate structure is disposed in the peripheral region of the substrate and the second gate structure located between the word line structure and the first gate structure, wherein a bottom surface of the second gate structure is coplanar with the top surface of the substrate.

According to some embodiments of the present disclosure, wherein the first gate structure includes a first dielectric layer, a first lower conductive layer, a first upper conductive layer, and a first cap layer. The first dielectric layer disposed below the top surface of the substrate. The first lower conductive layer disposed on the first dielectric layer. The first upper conductive layer disposed on the first lower conductive layer. The first cap layer disposed on the first upper conductive layer.

According to some embodiments of the present disclosure, wherein the first dielectric layer has a U-shape cross section.

According to some embodiments of the present disclosure, wherein a bottom surface of the first lower conductive layer is curved and is below the top surface of the substrate, and a top surface of the first lower conductive layer is above the top surface of the substrate.

According to some embodiments of the present disclosure, wherein the second gate structure includes a second dielectric layer, a second lower conductive layer, a second upper conductive layer, and a second cap layer. The second dielectric layer disposed on the top surface of the substrate. The second lower conductive layer disposed on the second dielectric layer. The second upper conductive layer disposed on the second lower conductive layer. The second cap layer disposed on the second upper conductive layer.

According to some embodiments of the present disclosure, wherein a first height from the top surface of the substrate to the top surface of the first lower conductive layer is equal to a second height from the top surface of the substrate to a top surface of the second lower conductive layer.

According to some embodiments of the present disclosure, wherein a first thickness at a central axis of the first lower conductive layer is greater than a second thickness at a central axis of the second lower conductive layer.

In accordance with an aspect of the present disclosure, a manufacturing method of a semiconductor device is provided. A word line structure is formed at an active region of a substrate. A hard mask layer is formed on the word line structure at the active region and a peripheral region of the substrate. A photo resist is formed on the hard mask layer, wherein the photo resist is located in the peripheral region of the substrate. The oxidation layer is formed to cover the photo resist and the hard mask layer. An etching back process is performed to remove a portion of the oxidation layer and to expose a top surface of the photo resist. The photo resist is stripped to form an opening in the oxidation layer. A portion of the hard mask layer and a portion of the substrate are removed through the opening in the oxidation layer such that a recess is formed, wherein a bottom surface of the recess is curved. A first gate structure is formed in the recess.

According to some embodiments of the present disclosure, wherein prior to form a first gate structure in the recess further includes removing the oxidation layer and the hard mask layer.

According to some embodiments of the present disclosure, wherein forming the hard mask layer includes forming an under layer on the substrate and forming an anti-reflection coating on the under layer.

According to some embodiments of the present disclosure, the method further includes forming a second gate structure in the peripheral region of the substrate and the second gate structure located between the word line structure and the first gate structure.

According to some embodiments of the present disclosure, wherein forming a first gate structure in the recess and forming the second gate structure include forming a dielectric layer on the substrate. A lower conductive layer is formed on the dielectric layer, wherein the recess is filled by the lower conductive layer and a top surface of the lower conductive layer is parallel to a top surface of the substrate. An upper conductive layer is formed on the lower conductive layer. A cap layer is formed on the upper conductive layer.

According to some embodiments of the present disclosure, the method further includes forming a first gate photo resist and a second gate photo resist on the cap layer, wherein the first gate photo resist is disposed on the recess, and the second gate photo resist is disposed between the word line structure and the first gate photo resist.

According to some embodiments of the present disclosure, the method further includes removing the cap layer, the upper conductive layer, lower conductive layer, and the dielectric layer that are not covered by the first gate photo resist and the second gate photo resist to form the first gate structure and the second gate structure.

According to some embodiments of the present disclosure, the method further includes stripping the first gate photo resist and the second gate photo resist.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view schematic diagram of a semiconductor device, in accordance with some embodiments;

FIG. 2 is a cross-sectional view schematic diagram of a semiconductor device after exposing a top surface of the substrate in the peripheral region, in accordance with some embodiments;

FIG. 3 is a cross-sectional view schematic diagram of a semiconductor device after forming a hard mask layer and a photo resist, in accordance with some embodiments;

FIG. 4 is a cross-sectional view schematic diagram of a semiconductor device after forming a oxidation layer covering the hard mask layer and the photo resist, in accordance with some embodiments;

FIG. 5 is a cross-sectional view schematic diagram of a semiconductor device after removing a portion of the oxidation layer, in accordance with some embodiments;

FIG. 6 is a cross-sectional view schematic diagram of a semiconductor device after stripping the photo resist, in accordance with some embodiments;

FIG. 7 is a cross-sectional view schematic diagram of a semiconductor device after etching a portion of the hard mask layer, in accordance with some embodiments;

FIG. 8 is a cross-sectional view schematic diagram of a semiconductor device after etching a portion of the substrate, in accordance with some embodiments;

FIG. 9 is a cross-sectional view schematic diagram of a semiconductor device after removing the hard mask layer, in accordance with some embodiments;

FIG. 10 is a cross-sectional view schematic diagram of a semiconductor device after forming a dielectric layer, lower conductive layer, upper conductive layer, and cap layer, in accordance with some embodiments;

FIG. 11 is a cross-sectional view schematic diagram of a semiconductor device after forming a first gate structure and a second gate structure, in accordance with some embodiments; and

FIG. 12 is an enlarged cross-sectional view schematic diagram of FIG. 11, in accordance with some embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

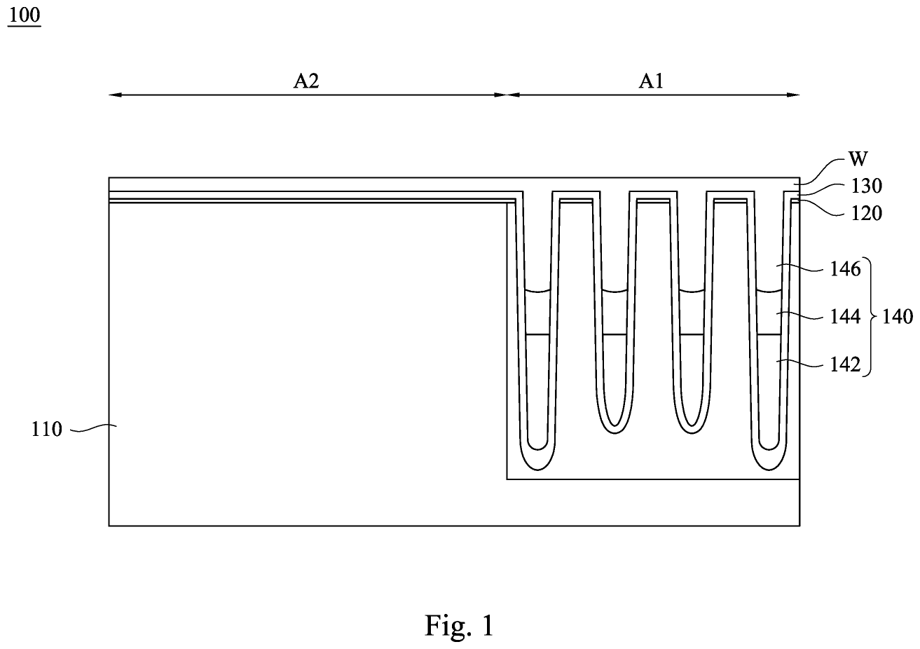

FIG. 1 is a cross-sectional view schematic diagram of a semiconductor device 100, in accordance with some embodiments. Referring to FIG. 1, the semiconductor device 100 includes a substrate 110, wherein substrate 110 having an active region A1 and a peripheral region A2 surrounding the active region A1. In some embodiments, the peripheral region A2 is located at the periphery of the substrate 110, and the active region A1 can be encircled by the peripheral region A2. In some embodiments, the substrate 110 may be, for example, a silicon (Si) substrate. Alternatively, the substrate 110 can is a Si substrate and is doped with other IV-IV, III-V or II-VI semiconductor materials. In some other embodiments, the substrate 110 may include a layered semiconductor such as silicon/silicon germanium, silicon-on-insulator, or silicon germanium-on-insulator.

In some embodiments, the active region A1 may be doped with an N-type dopant such as phosphorus (P), arsenic (As), or antimony (Sb). In some other embodiments, the active region A1 may be doped with a P-type dopant such as boron (B) or indium (In). In some embodiments, the substrate 110 may be or include an unimplanted area. In some embodiments, the active region A1 may have a higher doping concentration than the substrate 110.

In some embodiments, a hard mask 120 and an insulating layer 130 may be formed on the active region A1 and the peripheral region A2 of the substrate 110. In some embodiments, a gate structure 140 and word line structure W may be formed in the active region A1. The gate structure 140 may include a bottom conductive layer 142, a middle conductive layer 144, and a top conductive layer 146. The middle conductive layer 144 is formed on the bottom conductive layer 142. The top conductive layer 146 is formed on the middle conductive layer 144 and the top conductive layer 146 cover the insulating layer 130. In some embodiments, the material of the bottom conductive layer 142 can be metal nitride such as TiN. In some embodiments, the material of the middle conductive layer 144 can be poly-silicon. In some embodiments, the material of the top conductive layer 146 can be metal nitride such as TiN. The remaining portions of the material of the top conductive layer 146 on the substrate 110 can be regarded as the word line structure W, wherein the word line structure W is linear structure and connected to the corresponding gate structures 140.

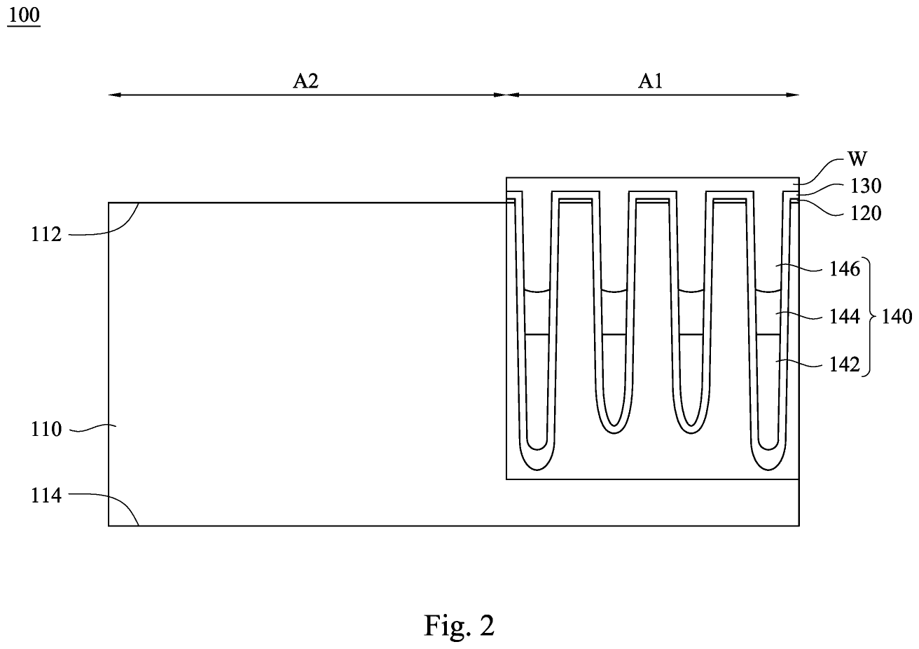

Referring to FIG. 2, forming a mask (not shown) covering the active region A1 of the substrate 110. After the mask is formed covering the active region A1 of the substrate 110, one or more etching processes are performed to remove the portions of the hard mask 120, the insulating layer 130, and the top conductive layer 146 that are not protected by the mask. The top surface 112 of the substrate 110 at the peripheral region A2 is exposed from the mask after the one or more etching processes are performed. Then the mask is removed after the removal of the portions of the hard mask 120, the insulating layer 130, and the top conductive layer 146.

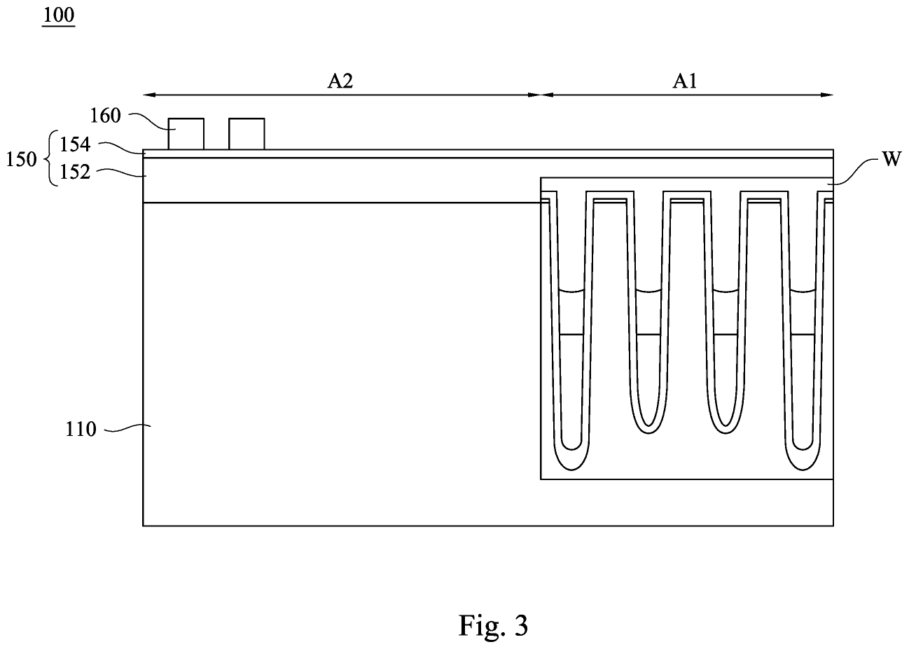

Referring to FIG. 3, a hard mask layer 150 is formed on the word line structure W at the active region A1 and the peripheral region A2 of the substrate 110. In some embodiments, the hard mask layer 150 includes an under layer 152 and an anti-reflection coating 154. The under layer 152 is formed on the substrate 110, and the anti-reflection coating 154 is formed on the under layer 152. Still refers to FIG. 3, a photo resist 160 is formed on the hard mask layer 150, wherein the photo resist 160 is located in the peripheral region A2 of the substrate 110. In other words, the photo resist 160 is formed on the anti-reflection coating 154.

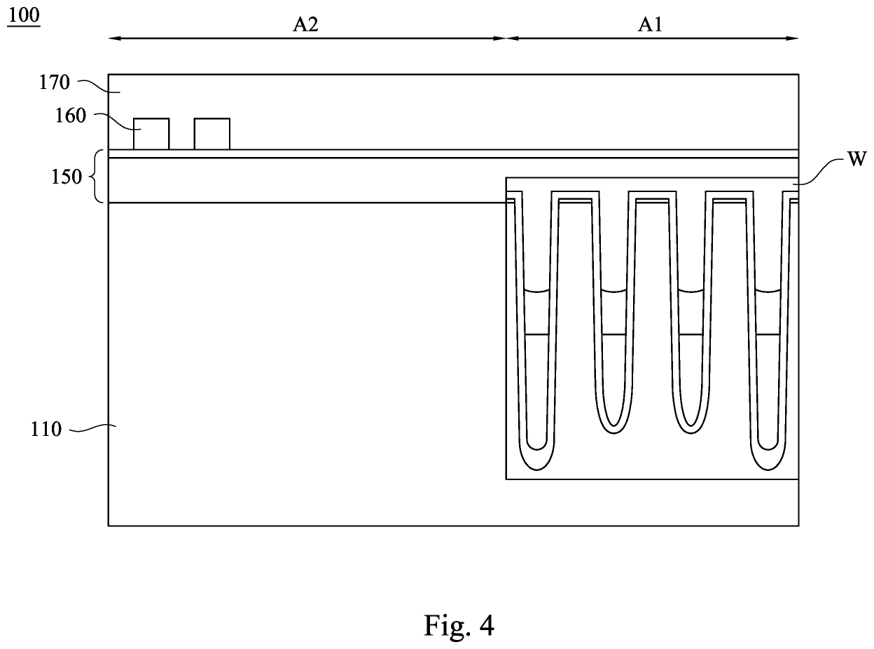

Referring to FIG. 4, an oxidation layer 170 is formed to cover the photo resist 160 and the hard mask layer 150. The oxidation layer 170 is formed by suitable deposition process, for example, chemical vapor deposition (CVD), atomic layer deposition (ALD), or physical vapor deposition (PVD). The oxidation layer 170 cover the photo resist 160 and the hard mask layer 150 located in the peripheral region A2. The oxidation layer 170 may cover the hard mask layer 150 located in the active region A1. The oxidation layer 170 may fill the gap between two photo resists 160.

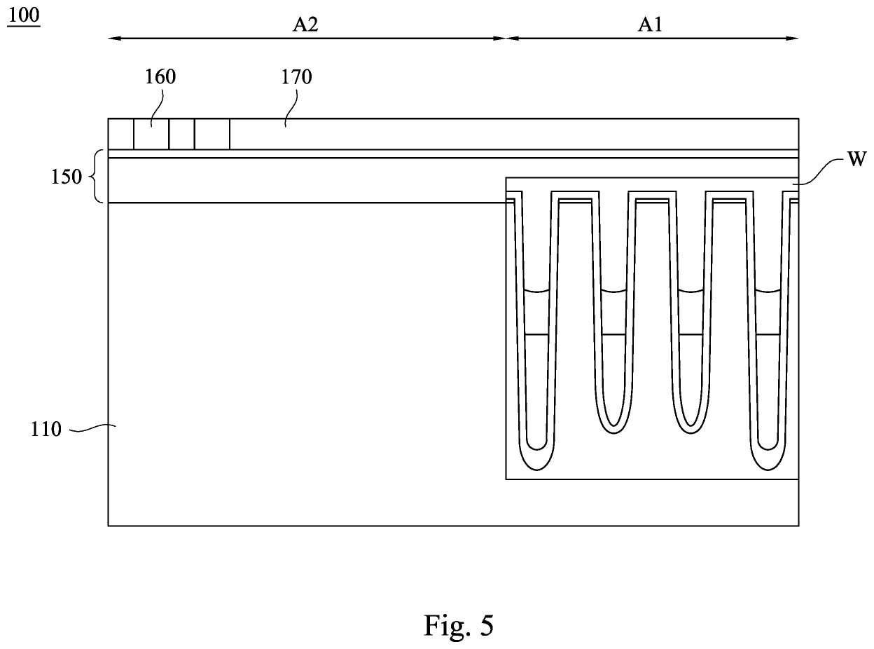

Referring to FIG. 5, a portion of the oxidation layer 170 is removed. In some embodiments, an etching back process is performed to remove a portion of the oxidation layer 170. After the etching back process is performed, a top surface of the photo resist 160 is exposed. For example, a chemical mechanical polish process may be performed, and the top surface of the photo resist 160 is coplanar with a top surface of the oxidation layer 170. In other words, the hard mask layer 150 located in the active region A1 is still covered by the oxidation layer 170.

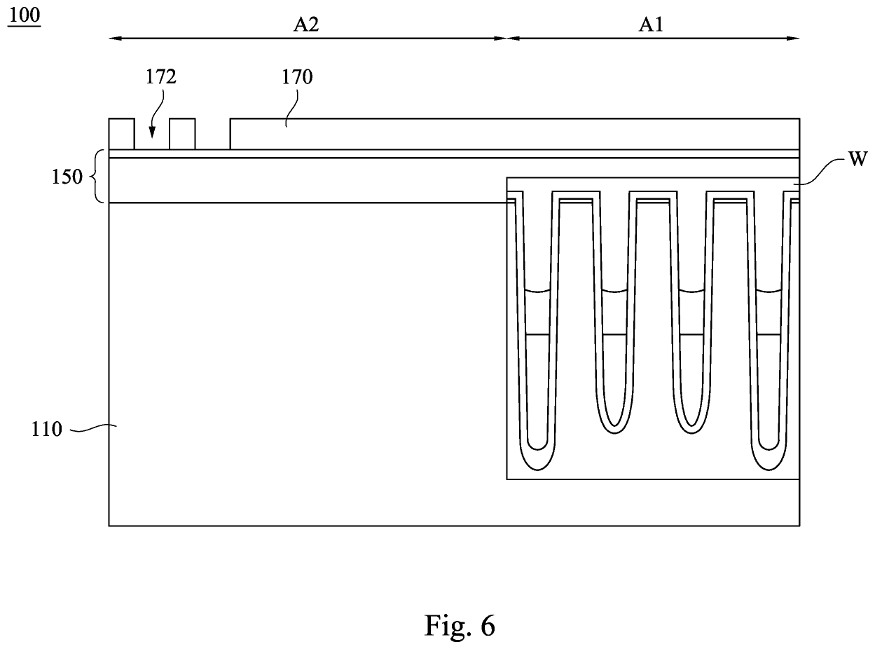

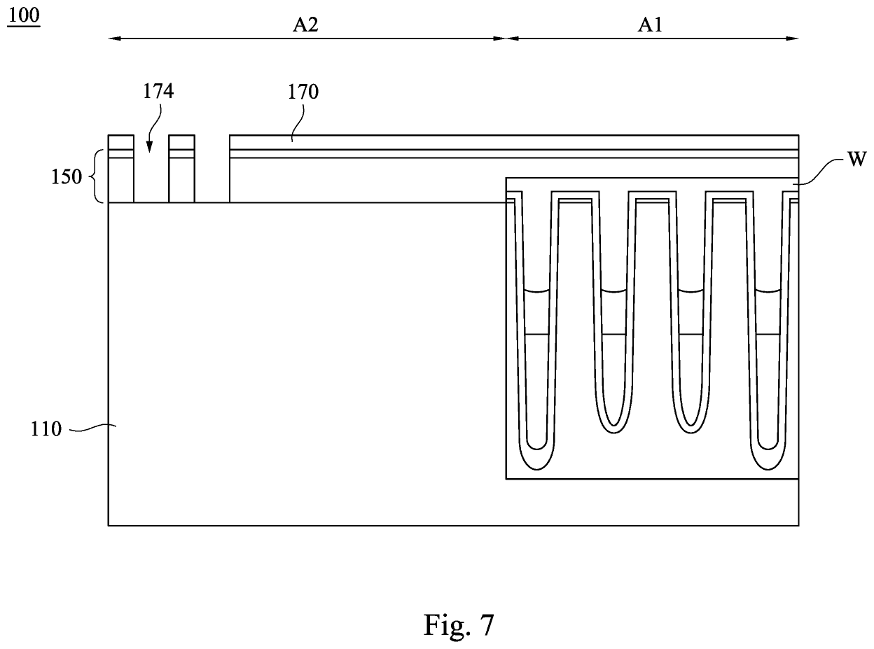

Next, referring to FIG. 6, the photo resist 160 is stripped to form an opening 172 in the oxidation layer 170 such that a top surface of the anti-reflection coating 154 is exposed. A portion of the oxidation layer 170 may be removed such that the thickness of the oxidation layer 170 being thinner. Referring to FIG. 7, a portion of the hard mask layer 150 is removed through the opening 172 such that an opening 174 is formed in the oxidation layer 170 and the hard mask layer 150. After the opening 174 is formed, a portion of the top surface 112 of the substrate 110 is exposed. The opening 174 is deeper than the opening 172. The bottom surface of the opening 174 is flat. In other words, the top surface 112 of the substrate 110 is not removed.

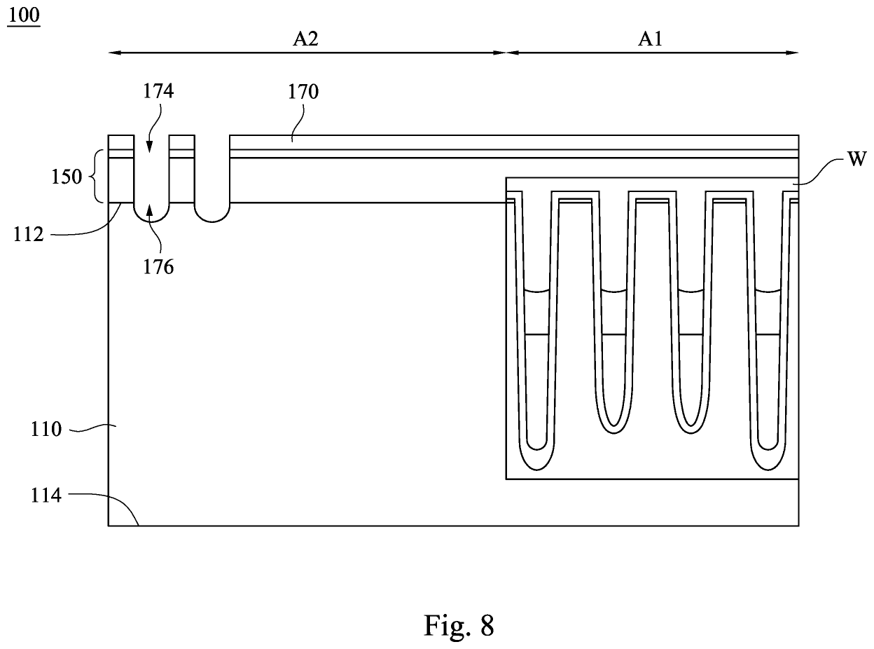

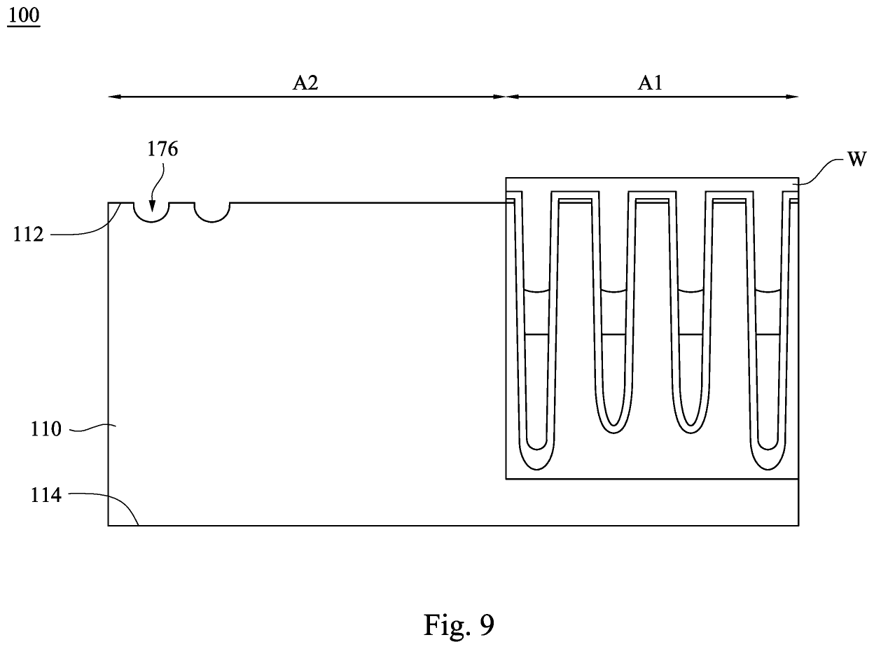

Referring to FIG. 8, a portion of the top surface 112 of the substrate 110 is removed through the opening 174 such that a recess 176 is formed in the substrate 110. In some embodiments, a bottom surface of the recess 176 is curved toward the bottom surface 114 of the substrate 110. The recess 176 has a substantially semicircular cross sectional shape. Referring to FIG. 9, the oxidation layer 170 and the hard mask layer 150 is removed such that the top surface 112 peripheral region A2 of the substrate 110 is exposed. In some embodiments, the word line structure W located in the active region A1 may be exposed.

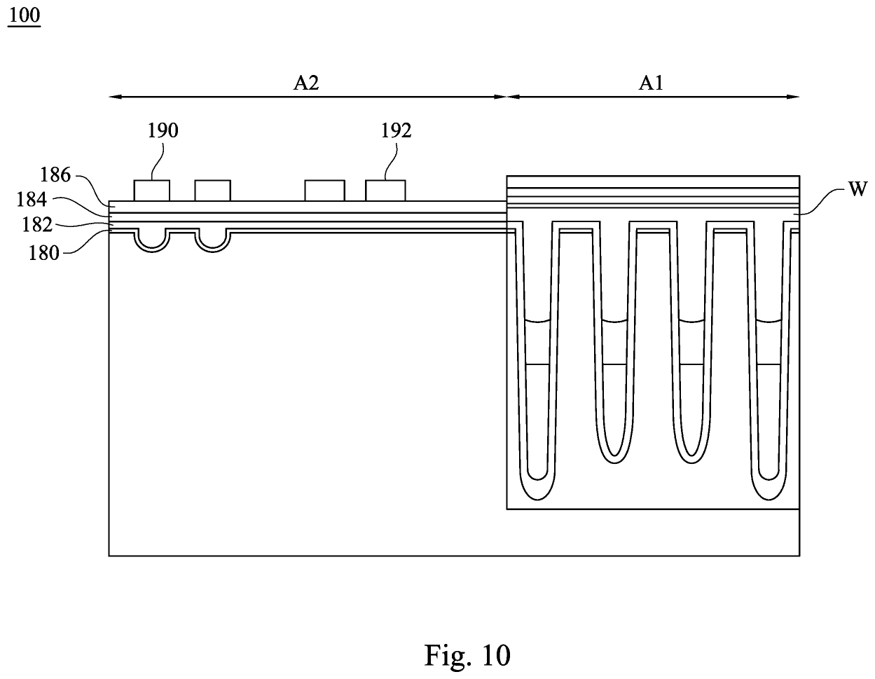

Referring to FIG. 10, a dielectric layer 180, a lower conductive layer 182, an upper conductive layer 184, and a cap layer 186 are formed on the on the substrate. Firstly, the dielectric layer 180 is formed on the substrate, wherein the dielectric layer 180 partially fills the recess 176. The lower conductive layer 182 is formed on the dielectric layer 180, wherein the recess 176 is filled by the lower conductive layer 182 and a top surface of the lower conductive layer 182 is parallel to a top surface 112 of the substrate 110. Then, the upper conductive layer 184 on the lower conductive layer 182. Finally, the cap layer 188 is formed on the upper conductive layer 184.

The dielectric layer 180, the lower conductive layer 182, the upper conductive layer 184, and the cap layer 186 are formed by suitable deposition process, for example, chemical vapor deposition (CVD), atomic layer deposition (ALD), or physical vapor deposition (PVD). In some embodiments, the dielectric layer 180 may include oxide. In some embodiments, the lower conductive layer 182 may include poly silicon. In some embodiments, the upper conductive layer 184 may include metal, for example, tungsten. In some embodiments, the cap layer 186 may include nitride.

Still refers to FIG. 10, a first gate photo resist 190 and a second gate photo resist 192 are formed on the cap layer 186, wherein the first gate photo resist 190 is disposed on the recess 176, and the second gate photo resist 192 is disposed between the word line structure W and the first gate photo resist 190.

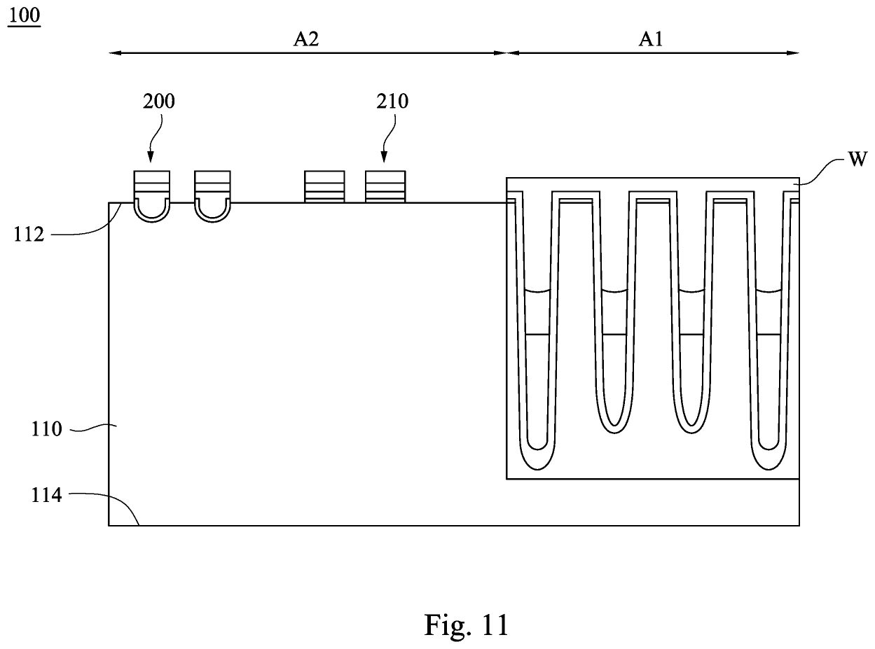

Referring to FIG. 11, removing the cap layer 186, the upper conductive layer 184 lower conductive layer 182, and the dielectric layer 180 that are not covered by the first gate photo resist 190 and the second gate photo resist 192 to form the first gate structure 200 and the second gate structure 210. Then, the first gate photo resist 190 and the second gate photo resist 192 are stripped.

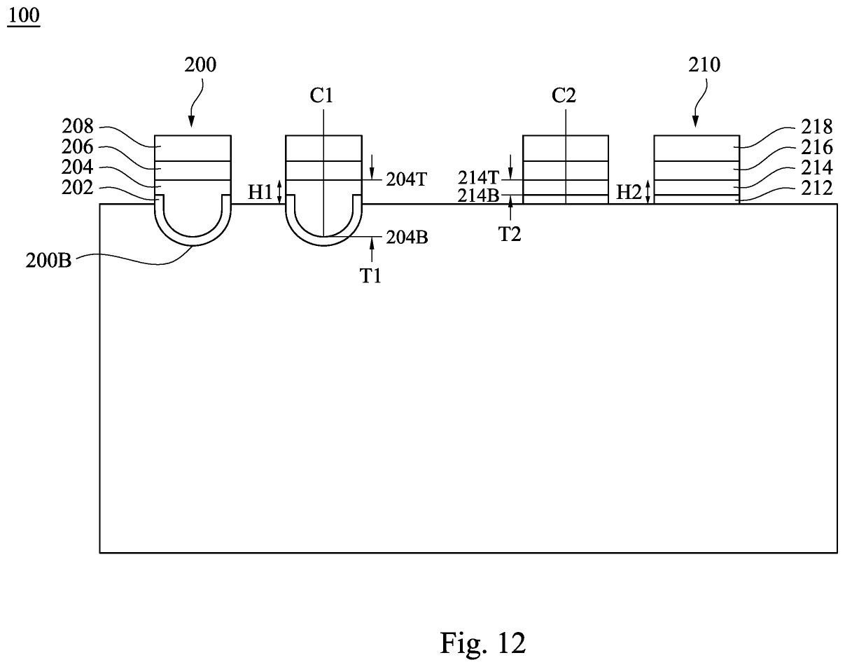

FIG. 12 is an enlarged cross-sectional view schematic diagram of FIG. 11. Referring to FIG. 11 and FIG. 12, the first gate structure 200 disposed in the peripheral region A2 of the substrate 110. A bottom surface of the first gate structure 200 is curved toward the bottom surface 114 of the substrate 110, and the bottom surface 200B of the first gate structure 200 is below a top surface 112 of the substrate 110. The second gate structure 210 disposed in the peripheral region A2 of the substrate 110, and the second gate structure 210 is located between the word line structure W and the first gate structure 200, wherein a bottom surface 210B of the second gate structure 210 is coplanar with the top surface 112 of the substrate 110.

The first gate structure 200 includes a first dielectric layer 202, a first lower conductive layer 204, a first upper conductive layer 206, and a first cap layer 208. The first dielectric layer 202 is disposed below the top surface 112 of the substrate 110. The first lower conductive layer 204 disposed on the first dielectric layer 202. The first upper conductive layer 206 is disposed on the first lower conductive layer 204. The first cap layer 208 is disposed on the first upper conductive layer 206.

In some embodiments, the first dielectric layer 202 has a U-shape cross section. The bottom surface 204B of the first lower conductive layer 204 is curved and is below the top surface 112 of the substrate 110, and a top surface 204T of the first lower conductive layer 204 is above the top surface 112 of the substrate 110.

The second gate structure 210 includes a second dielectric layer 212, a second lower conductive layer 214, a second upper conductive layer 216, and a second cap layer 218. The second dielectric layer 212 is disposed on the top surface 112 of the substrate 110. The second lower conductive layer 214 disposed on the second dielectric layer 212. The second upper conductive layer 216 is disposed on the second lower conductive layer 214. The second cap layer 218 is disposed on the second upper conductive layer 216.

In some embodiments, a first height H1 from the top surface 112 of the substrate to the top surface 204T of the first lower conductive layer 204 is equal to a second height H2 from the top surface 112 of the substrate to a top surface 214T of the second lower conductive layer 214. In some embodiments, a first thickness T1 at a first central axis C1 of the first lower conductive layer 204 is greater than a second thickness T1 at a second central axis C2 of the second lower conductive layer 214.

The present disclosure provides a manufacturing method of semiconductor device. The peripheral region of the semiconductor device including a first gate structure and a second gate structure. The bottom surface of the first gate structure is curved, and the bottom surface of the second gate structure is flat. The first gate structure may support larger drive current. The semiconductor device of the present disclosure may improve leakage issue.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor device, comprising:
a substrate having an active region and a peripheral region surrounding the active region;
a word line structure disposed in the active region of the substrate;
a first gate structure disposed in the peripheral region of the substrate, wherein a bottom surface of the first gate structure is curved toward the substrate, and the bottom surface of the first gate structure is below a top surface of the substrate; and
a second gate structure disposed in the peripheral region of the substrate and the second gate structure located between the word line structure and the first gate structure, wherein a bottom surface of the second gate structure is coplanar with the top surface of the substrate.

2. The semiconductor device of claim 1, wherein the first gate structure comprises:
a first dielectric layer disposed below the top surface of the substrate;
a first lower conductive layer disposed on the first dielectric layer;
a first upper conductive layer disposed on the first lower conductive layer; and
a first cap layer disposed on the first upper conductive layer.

3. The semiconductor device of claim 2, wherein the first dielectric layer has a U-shape cross section.

4. The semiconductor device of claim 2, wherein a bottom surface of the first lower conductive layer is curved and is below the top surface of the substrate, and a top surface of the first lower conductive layer is above the top surface of the substrate.

5. The semiconductor device of claim 2, wherein the second gate structure comprises:
a second dielectric layer disposed on the top surface of the substrate;
a second lower conductive layer disposed on the second dielectric layer;
a second upper conductive layer disposed on the second lower conductive layer; and
a second cap layer disposed on the second upper conductive layer.

6. The semiconductor device of claim 5, wherein a first height from the top surface of the substrate to the top surface of the first lower conductive layer is equal to a second height from the top surface of the substrate to a top surface of the second lower conductive layer.

7. The semiconductor device of claim 5, wherein a first thickness at a central axis of the first lower conductive layer is greater than a second thickness at a central axis of the second lower conductive layer.

8. A manufacturing method of a semiconductor device, comprising:
forming a word line structure at an active region of a substrate;
forming a hard mask layer on the word line structure at the active region and a peripheral region of the substrate;
forming a photo resist on the hard mask layer, wherein the photo resist is located in the peripheral region of the substrate;
forming an oxidation layer to cover the photo resist and the hard mask layer;
performing an etching back process to remove a portion of the oxidation layer and to expose a top surface of the photo resist;
stripping the photo resist to form an opening in the oxidation layer;
etching a portion of the hard mask layer and a portion of the substrate through the opening in the oxidation layer such that a recess is formed, wherein a bottom surface of the recess is curved; and
forming a first gate structure in the recess.

9. The manufacturing method of a semiconductor device of claim 8, wherein prior to form a first gate structure in the recess further comprises:
removing the oxidation layer and the hard mask layer.

10. The manufacturing method of a semiconductor device of claim 8, wherein forming the hard mask layer comprises:
forming an under layer on the substrate; and
forming an anti-reflection coating on the under layer.

11. The manufacturing method of a semiconductor device of claim 8, further comprising:
forming a second gate structure in the peripheral region of the substrate and the second gate structure located between the word line structure and the first gate structure.

12. The manufacturing method of a semiconductor device of claim 11, wherein forming a first gate structure in the recess and forming the second gate structure comprise:
forming a dielectric layer on the substrate;
forming a lower conductive layer on the dielectric layer, wherein the recess is filled by the lower conductive layer and a top surface of the lower conductive layer is parallel to a top surface of the substrate;
forming an upper conductive layer on the lower conductive layer; and
forming a cap layer on the upper conductive layer.

13. The manufacturing method of a semiconductor device of claim 12, further comprising:
forming a first gate photo resist and a second gate photo resist on the cap layer, wherein the first gate photo resist is disposed on the recess, and the second gate photo resist is disposed between the word line structure and the first gate photo resist.

14. The manufacturing method of a semiconductor device of claim 13, further comprising:
removing the cap layer, the upper conductive layer, lower conductive layer, and the dielectric layer that are not covered by the first gate photo resist and the second gate photo resist to form the first gate structure and the second gate structure.

15. The manufacturing method of a semiconductor device of claim 14, further comprising:
stripping the first gate photo resist and the second gate photo resist.
